(19) United States
(12) Patent Application Publication
(10) Pub. No.: US 2023/0024045 A1
(43) Pub. Date: Jan. 26, 2023

(54) SEMICONDUCTOR TESTING APPARATUS WITH ADAPTOR

(71) Applicant: TEST21 TAIWAN CORPORATION, Hsinchu (TW)

(72) Inventor: Shun-Bon Ho, Hsinchu (TW)

(21) Appl. No.: 17/865,419

(22) Filed: Jul. 15, 2022

(30) Foreign Application Priority Data
Jul. 16, 2021 (TW) 110126255

(51) Int. Cl. G01R 31/26; G01R 1/067; G01R 1/073

(52) U.S. Cl. CPC G01R 31/2601; G01R 1/06744; G01R 1/07314

(57) ABSTRACT

The present disclosure provides a semiconductor testing apparatus with a connected unit, which is applied to a wafer probing testing or a final testing. The semiconductor testing apparatus comprises a semiconductor testing printed circuit board, a functional module and the connected unit. First contact points are disposed on a first surface of the semiconductor testing printed circuit board, and electrically connected to the functional module. Second contact points are disposed on a second surface of the semiconductor testing printed circuit board, and electrically connected to a functional controller. The first contact points and the second contact points have independent and non-interfering working time domains. Therefore, the present disclosure can utilize the area of the semiconductor testing printed circuit board, and can independently perform functional testing of a wafer or packaged integrated circuit devices using multiple time domains, in a multi-time domain, synchronous or asynchronous manner.

### CROSS-REFERENCE TO RELATED APPLICATION

This application claims the priority from TW Patent Application No. 110126255, filed on Jul. 16, 2021, and all contents of such TW Patent Applications are included in the present disclosure.

### BACKGROUND

### 1. Field of the Invention

The present disclosure relates to a semiconductor testing apparatus with a connected unit for testing a functional controller, in particular to, a semiconductor testing apparatus capable of testing a function of a functional controller in parallel through a synchronous or asynchronous time domain independently.

### 2. Description of the Related Art

In a process of semiconductor testing, a wafer probing testing and a final testing are often comprised. The purpose of the wafer probing testing and the final testing is to screen the performance of each die on a wafer or semiconductor product (such as packaged integrated circuit device, packaged IC device). Moreover, during the wafer probing testing and the final testing, the dice or packaged IC devices with signal transmission defects can be excluded to be prevented from being transmitted to the next process or market. Therefore, by timely screening out the defective dice or packaged IC device during the testing stage, it is possible to prevent from spending a lot of process time and cost on the defective dice or package ICs, result in low production performance and efficiency.

Additionally, in the wafer probing testing and the final testing, since an integrated circuit device to be tested (that is, a device under test, DUT) often needs to be tested together a plurality of functional components, it is often necessary to perform production testing through a plurality of adapters at the same time. However, these adapters occupy a large area and space, so it is necessary to increase the board area required for testing with these adapters.

In order to test integrated circuits (IC), loadboards (commonly known as PCBs) connected to an automatic test equipment (referred as ATE or tester) have to be designed to accommodate a socket for testing the DUT and all related components electrically connected to the DUT. Besides, to simulate various operating environments, the operating environments of actual products are directly reproduced for testing. Ideally, for manufacturing a loadboard with high density and high performance, the distances between each component should be as short as possible. Due to the limitations of many devices, component space on the loadboard is critical. As a result, many manufacturers of printed circuit boards (PCBs) are faced with the difficulty of deciding which components are best placed next to the DUT. In most cases, they have no choice but to divide a test circuit into multiple sets of hardware to meet the needs of product testing. From an economic point of view, the multiple insertion/withdrawal tests, test cycles and other labor and material costs that are required would significantly increase the cost of IC manufacturing. At the same time, it also causes delays in the time of product launch.

In addition, due to the limited space of the printed circuit board as an electrical connection medium, the functional components that can be mounted in the limited space are even more limited. If the problem of wiring layout is considered, the printed circuit board of existing testing apparatuses is not suitable for placing a large number of functional components in it at all. Hence, the number of wafers and dice (or packaged IC devices) that can be simultaneously tested in the wafer probing testing or the final testing would be limited by the space of the printed circuit board or the functional components on the printed circuit board. Thus, only a relatively small number of wafers and dice (or packaged IC devices) can be tested at the same time, which is quite time-consuming. In the related art, even though the plurality of functional components can still be placed on the printed circuit board, the distance between the functional components is long. As a result, the distance of the signal transmission path between the functional component and the functional controller is long, and even the placement of the functional component and a circuit layout may have asymmetric characteristics problems. As a result, the testing accuracy would be greatly reduced.

Further, due to the functional controller disposed on the wafer, the testing cannot be performed in parallel and in an asynchronous time domain manner at the same time. Thus, the number of functional controllers on the wafer that can be tested by a plurality of multi-site touchdowns is quite limited, which consumes a lot of unnecessary testing time and cost. Consequently, currently, the semiconductor testing apparatus for testing functional controllers simply perform low-density and low-speed tests on the functional controllers.

Based on the above various situations, there are problems as follows to be solved in the technical field. Firstly, how to use the surface area of the printed circuit board more effectively to increase the utilization rate of the printed circuit board. Secondly, how to make the distance between each component kept as short as possible to reduce the transmission signal attenuation and distortions. Thirdly, how to increase the number of sites of the multi-site touchdowns, for example, from 4 wafer dice at one time to 8 wafer dice at one time, so as to reduce the number of touches. In the wafer probing testing and the finally testing, by reducing the number of touchdowns, more wafer probing testing and finally testing can be effectively completed in a shorter period. As well, by reducing the number of touchdowns, the qualified functional controllers are able to be determined quickly.

### SUMMARY

In order to solve the preceding problems, embodiments of the present disclosure provide a semiconductor testing apparatus with a connected unit. The semiconductor testing apparatus is configured to test a functionality of an integrated circuit on a wafer or in a packaged integrated circuit device (packaged IC device).

The embodiments of the present disclosure provide the semiconductor testing apparatus with the connected unit. The semiconductor testing apparatus provides contact points on an upper side and a lower side of a semiconductor testing printed circuit board (PCB) (for convenience of description, the contact points on a first surface of the PCB are called first contact points; alternatively, the contact points on a second surface opposite to the first surface of the PCB are called second contact points) which are electrically connected to each other by arranging a combination of vertical wires an non-vertical wires in the semiconductor testing printed circuit board. In addition to keeping a certain vertical distance between the first contact points and some of the second contact points, a certain horizontal distance may also be maintained at the same time. By arranging the first contact points and the second contact points, a smaller area can be expanded to a larger layout area. In this way, the number of DUTs disposed on the PCB can be increased, so that the test efficacy is greatly improved.

Since a plurality of functional controllers on the wafer or the packaged integrated circuit device (packaged IC device) are independently electrically connected to the PCB and connected functional modules on it through the second contact points, an embodiment of the present disclosure enables the functional controllers to input/output functional signals independently in a synchronous or asynchronous manner, so as to effectively test functions of each functional module by each functional controller. Accordingly, in the wafer probing testing, the number of sites of the multi-site touchdown probes can be effectively increased. Thus, the number of touchdowns required for testing can be reduced, so the time and cost required for testing can be substantially reduced.

Generally speaking, the semiconductor testing apparatus comprises a semiconductor testing printed circuit board and a functional module. The semiconductor testing printed circuit board comprises a plurality of first contact points, a plurality of second contact points and a plurality of specific through-board connections. The specific through-board connections are disposed in the semiconductor testing printed circuit board. The specific through-board connections are vertically or non-vertically electrically connected to the first contact points and part of the second contact points, respectively. Besides, each of the second contact points is electrically connected to one of the first contact points, respectively. The functional module is disposed on the semiconductor testing printed circuit board, and the functional module is electrically connected to the first contact points of the semiconductor testing printed circuit board.

In the wafer probing testing, according to an embodiment, the semiconductor testing apparatus comprises a primary space transformer device and a plurality of probe pins. The primary space transformer device is disposed on the second surface of the semiconductor testing printed circuit board. The primary space transformer device comprises a plurality of third contact points and a plurality of fourth contact points. The third contact points are disposed on a third surface of the first adaptor, and the third contact points are electrically connected to the second contact points. The fourth contact points are disposed on a fourth surface opposite to the third surface of the primary space transformer device, and each of the fourth contact points is electrically connected to one of the third contact points. The probe pins are electrically connected to the fourth contact points and the functional controllers on the wafer. Thereby, the function of each functional controller to the functional module is independently tested in the synchronous or asynchronous time domain.

In the wafer probing testing, according to an embodiment, the functional module is a dynamic random access memory, a static random access memory, a static dynamic random access memory, a flash memory or a combination thereof.

In the wafer probing testing, according to another embodiment, the functional controllers are a memory controller or a direct memory access controller.

In the wafer probing testing, according to another embodiment, the probe components are a vertical probe component, such as a cobra probe, a MEMS (micro-electrical-mechanical system) probe, a MEMS POGO, a wire probe, a POGO pin or a combination thereof.

In the final testing, according to an embodiment, the second contact points are electrically connected to the packaged IC device, so as to test the function of each functional controller to the functional module with the synchronous or asynchronous time domain independently.

In the final testing, according to another embodiment, the semiconductor testing apparatus further comprises a plurality of sockets. The sockets are respectively disposed on the semiconductor testing printed circuit board to accommodate the packaged IC devices respectively.

In the final testing, according to another embodiment, the probe components are a cobra probe, a MEMS probe, a wire probe or a combination thereof.

In the wafer probing testing and the final testing, according to an embodiment, the first contact points electrically connected to the part of the second contact points are disposed apart from each other by a certain horizontal offset.

Further, the connected unit is electrically connected to the DUT by the specific through-board connections penetrating through the semiconductor testing printed circuit board. Therefore, the DUT is electrically connected with the connected unit in the shortest distance, so as to effectively shorten the signal transmission distance between the DUT and the connected unit. Consequently, the problem of signal attenuation in the transmission process caused by the arrangement of the connected unit and the DUT in the related art is solved. As a result, more of the PCB area can be utilized. As well, in the case of the same unit PCB area, a larger number of the connected unit or DUT can be tested, and the time and cost required for testing can be successfully reduced.

As the internal feature size of ICs continues to decrease, current wafer manufacturing processes have effectively reduced a signal voltage level to about 0.75 V. Thus, signal noise immunity and power delivery network (PDN) impedance have gradually become key challenges for test fixtures and test methods. The present disclosure solves the preceding problems by effectively shortening the path distance between components, and thus critically reducing the parasitic resistance, inductance and capacitance. Accordingly, the DUT can be operated over a wider performance range, with higher operating speed limits, stronger signals, and lower PDN inductance, which allows for high data-rate and reducing overall signal-to-noise ratio.

Specifically, the present disclosure also provides another semiconductor testing apparatus with a connected unit. The semiconductor testing apparatus comprises a semiconductor testing printed circuit board and a second connected unit.

The semiconductor testing apparatus comprise at least two sockets and a plurality of specific through-board connections. The at least two sockets are disposed adjacently on a second surface of the semiconductor testing printed circuit board. The at least two socket are configured to load a packaged integrated circuit device (packaged IC device), respectively. The specific through-board connections are disposed opposite to the sockets. The specific through-board connections penetrate through the semiconductor testing printed circuit board to be electrically connected to the packaged IC device.

According to an embodiment, the semiconductor testing printed circuit board comprises simply one socket which is configured to load the packaged IC device.

The second connected unit is disposed on a first surface of the semiconductor testing printed circuit board relative to the socket. The second connected unit is electrically connected to the specific through-board connections with the shortest distance, so as to reduce the signal attenuation between the second connected unit and the socket.

According to another embodiment, the second connected unit has a plurality of probes, and the probes are configured to directly contact the specific through via holes.

According to another embodiment, the probes are POGO pins, Elastomer, vertical conduction probes, board-to-board connectors, or other contact probes.

According to another embodiment, the second connected unit comprises a high-speed component, a low-noise component or a combination thereof.

According to another embodiment, a high-speed component comprises solid state relay (SSR), high-speed connectors, memories, radio frequency passive components (RF passive components) and radio frequency active components (RF active components).

According to another embodiment, high-speed signals of the high-speed component comprise serial advanced technology attachment (SATA) interface, a peripheral component Interconnect express (PCIe) interface, a universal serial bus (USB) interface, a mobile industry processor interface (MIPI), a high definition multimedia interface (HDMI), a memory interface, a radio frequency (RF) interface, or a combination thereof.

According to another embodiment, the memory interface comprises a double data rate (DDR) memory interface, a flash memory interface, or a combination thereof.

According to another embodiment, the low-noise components comprise an operational amplifier (OP), a digital to analog converter (DAC), an analog to digital converter (ADC) and an image sensor.

According to another embodiment, a high-density package of the DUT is a ball grid array (BGA) package or a chip scale package (CSP).

Furthermore, the present disclosure also provides a semiconductor testing method with the connected unit. The method comprises the following steps.

The at least two sockets are disposed adjacently on the second surface of the semiconductor testing printed circuit board. The semiconductor testing printed circuit board has the plurality of specific through-board connections, and the specific through-board connections are disposed relative to the sockets and penetrate through the semiconductor testing printed circuit board.

The plurality of second connected units are disposed on the first surface of the semiconductor testing printed circuit board opposite to the second surface relative to the sockets. The second connected units are electrically connected to part of the specific through-board connections.

The DUTs are disposed on the sockets, respectively. Due to the socket being electrically connected to the specific through-board connections, the DUTs is able to be electrically connected to the second connected units and the sockets with the shortest distance, so as to perform a semiconductor test.

According to another embodiment, the probe is POGO pins or vertical conductive probes.

As the stated as the above embodiments, the present disclosure can achieve the following effects.

Firstly, in the embodiments of the present disclosure, the specific through-board connections, which are vertical or non-vertical, are variously disposed in the semiconductor testing printed circuit board to make the first contact points and the second contact points be electrically connected to each other. As well, through the stacking of the functional modules, the number of the DUTs can be increased. In other words, on the semiconductor testing printed circuit board with a limited area, the functional modules are capable of being electrically connected to the first contact points more effectively. Therefore, in a unit time, more wafers and dice (or packaged IC devices) on the wafer can be tested in parallel for each functional controller to perform functional tests with a functional module.

Secondly, at the same time, due to the arrangement of the first contact points and the second contact points, the embodiments of the present disclosure can simultaneously make the plurality of independent functional controllers contact the second contact points respectively. By being electrically connected each functional controller to the functional module, the functional testing of each functional controller to the functional module can be performed in an independent and parallel time domain in a synchronous or asynchronous manner.

Thirdly, due to the increase in the number of sites of multi-site touchdowns, the functional controllers on the wafer can operate synchronously or asynchronously in independent and parallel time domains to perform the function tests. Thus, the number of the touchdowns can be reduced.

Fourthly, because a combination of vertical wires and non-vertical specific through-board connections is provided in the semiconductor testing printed circuit board, the contact points between the first surface (the upper surface) and the second surface (the lower surface) of the semiconductor testing printed circuit board are electrically connected. Therefore, the distance between the signal transmission paths between the functional module and the functional controller is the same, which is different from the need to perform multi-site correlations in the related art. Even, the placement of the functional modules and the circuit layout will not cause asymmetric characteristics problems, so as to greatly improve the testing accuracy.

Fifthly, compared with the related art, the present disclosure can effectively utilize the PCB to increase the number of the connected units or DUTs that can be accommodated per unit area. In addition, in the case of the same PCB area, a large number of DUTs can be tested.

Sixthly, since each connected unit and each corresponding DUT are disposed at the shortest distance. The shortest distance disposed ensures that the signal is transmitted in an environment with low resistance, low inductance and low capacitance. Therefore, the present disclosure can still provide high-current and high-speed signals in current low-voltage environment. That is, in addition to reducing the attenuation of the test signal by the transmission distance between the connected unit and the DUT, the electrical performance of the connected unit can be improved.

Seventhly, due to the design of the shortest distance, the present disclosure can further improve the exponential decrease of the test signal caused by the long transmission distance of the test signal in the related art. Besides, the present disclosure can also improve the misjudgment in subsequent testing (for example, a normal DUT is judged as an unqualified DUT), even reduce the yield rate of products caused by the long transmission distance of the test signal in the related art.

Eighthly, the present disclosure does not need to test the DUTs of different functions separately (multiple insertion). Therefore, a part of the testing procedure can be omitted, so as to shorten the time required and reduce the cost required in the test procedure.

In view of the above, the present disclosure can more effectively improve the test density by stacking the functional modules through the second connected unit, and increase the utilization rate per unit area. Furthermore, due to the arrangement of the first contact points and the second contact points, the number of the single sites of the wafers that are touched by the multi-site probe is increase, so the time required for testing can be shorten and the cost required for testing can be reduced.

### BRIEF DESCRIPTION OF THE DRAWINGS

FIG. 1 is a schematic diagram of a semiconductor testing apparatus with a functional module, configured to test a functional controller in an independent time domain in a wafer probing testing according to an embodiment of the present disclosure;

FIG. 2 a schematic diagram of a semiconductor testing apparatus with a functional module, which is configured to test a functional controller with an independent time domain in a final testing;

FIG. 3 is a schematic three-dimension diagram of a semiconductor testing device with a connected unit according to an embodiment of the present disclosure;

FIG. 4 is a cross-section diagram along a tangent A-A′ in FIG. 3 of a structure of the semiconductor testing device with the connected unit according to an embodiment of the present disclosure.

### DESCRIPTION OF THE PREFERRED EMBODIMENTS

In the view of the preceding problems to be overcome, an embodiment of the present disclosure develops a semiconductor testing apparatus. The semiconductor testing apparatus comprises functional modules and the semiconductor testing apparatus is configured to test functional controllers with an independent time domain. The semiconductor testing apparatus comprises a semiconductor testing printed circuit board (PCB) and a plurality of functional modules. The functional modules are electrically connected to a first surface of the semiconductor testing printed circuit board through a plurality of first contact points. During a wafer probing testing, the functional modules are electrically connected to a wafer and the functional controllers on the wafer through a plurality of second contact points disposed on a second surface (the second surface opposite to the first surface) of the semiconductor testing printed circuit board. Alternatively, in a final testing, the functional modules are electrically connected to a packaged integrated circuit device (packaged IC device) and the functional controller in the packaged IC device through the plurality of second contact points disposed on the second surface of the semiconductor testing printed circuit board. Since the first contact points and the second contact points are electrically connected to each other through vertical or non-vertical specific through-board connections, it is possible to increase the number of sites of the wafer that can be touched, for example, from the original touchdown of 4 wafer dice at one time to the touchdown of 8 wafer dice at one time. Hence, the number of touchdown can be reduced in the wafer probing testing and the final testing. As a result, more wafer probing testing and final testing are effectively completed in a shorter time. Even, a single functional module is electrically connected to the plurality of functional controllers with an independent time domain, so as to test whether the functional controllers can successfully function on the functional module in a synchronous or asynchronous manner.

Additionally, the functional controller tested by the semiconductor testing apparatus provided by an embodiment of the present disclosure refers to an electronic device that performs functional testing on high-density and high-speed functional modules. The high-density and high-speed functional modules is tested by using the semiconductor testing apparatus of the embodiment of the present disclosure, so as to determine whether the functional testing of the functional modules is normal, but the present disclosure is not limited thereto.

In order to explain various embodiments of the present disclosure more clearly, the following description is supplemented by the accompanying drawings.

### [Wafer Probing Testing]

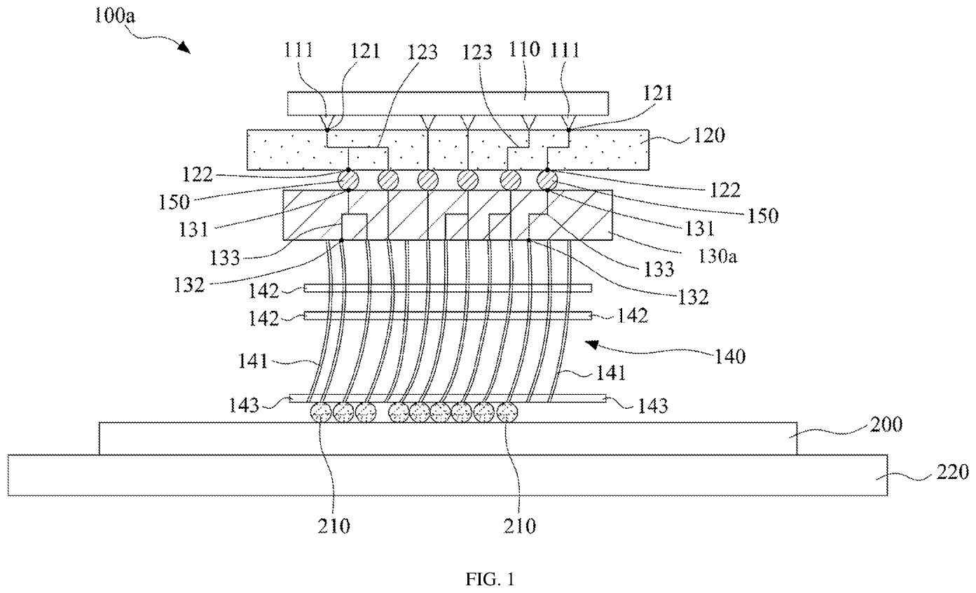

Referring to FIG. 1, FIG. 1 is a schematic diagram of a semiconductor testing apparatus with a functional module, configured to test a functional controller in an independent time domain in a wafer probing testing according to an embodiment of the present disclosure. In FIG. 1, according to an embodiment, the semiconductor testing apparatus 100a comprises a functional module 110, which is configured to test a functional controller. The semiconductor testing apparatus performs the wafer probing testing by being electrically connected to a wafer 200 disposed on a wafer chuck 220 and dice on the wafer 200. On each of the wafer 200 and the dice on the wafer 200 are disposed a plurality of functional controllers. Each of the functional controllers has its own independent time domain, which is configured to test a function of the functional controllers with the functional module in a synchronous or asynchronous manner.

More specifically, the semiconductor testing apparatus 100a comprises a semiconductor testing printed circuit board 120 and a plurality of functional modules 110. Each of the functional modules 110 has different independent time domains based on the plurality of tested functional controllers. In this way, the plurality of functional controllers may correspond to one functional module 110, or one functional controller may correspond to one functional module 110. Thus, each of the functional controllers is able to be electrically connected to the same functional module 110. Due to different independent time domain, the semiconductor testing apparatus 100a can test the plurality of functional controllers in parallel at the same time.

The semiconductor testing printed circuit board 120 is further described as follows. The semiconductor testing printed circuit board 120 comprises a plurality of first contact points 121, a plurality of second contact points 122 and a plurality of specific through-board connections 123.

The first contact points 121 are respectively disposed on a first surface of the semiconductor testing printed circuit board 120 (for example, an upper side of the semiconductor testing printed circuit board 120 in FIG. 1). The second contact points 122 are respectively disposed on a second surface opposite to the first surface of the semiconductor testing printed circuit board 120 (for example, a lower side of the semiconductor testing printed circuit board 120 in FIG. 1), so as to be electrically connected to the functional controllers disposed on the wafer 200 (and the dice on the wafer 200). Next, the specific through-board connections 123 are disposed in the semiconductor testing printed circuit board 120. The specific through via holes 123 are vertically or non-vertically electrically connected to the first contact points 121 and a part of the second contact points 122, respectively. Since each of the second contact points 122 is electrically connected to one of the first contact points 121, respectively, each of the first contact points 121 is electrically connected to the plurality of second contact points in a one-to-many manner. However, each of the second contact points 122 is only electrically connected to a single first contact point 121 respectively, and each of the second contact points 122 cannot be electrically connected to the plurality of first contact points 121 at the same time. That is, the plurality of functional controllers may correspond to one functional module 110, or one functional controller may correspond to one functional module 110.

It should be noted that not all the first contact points 121 need to be electrically connected to the second contact points 122, and not all the second contact points 122 need to be electrically connected to the first contact points 121 either. That is, according to an embodiment, some of the specific first contact points 121 are electrically connected to some of the specific second contact points 122 in the one-to-many manner.

The functional modules 110 are stacked on the semiconductor testing printed circuit board 120 by adjusting a connection manner of the specific through-board connections 123 in vertical or non-vertical combinations. Consequently, the more functional modules 110 can be disposed on the same semiconductor testing printed circuit board 120. Also, the functionality of more functional controllers on the wafer 200 connected to functional modules are tested in parallel in a specific period.

According to an embodiment, when the first contact points 121 are electrically connected to part of the second contact points 122 with the non-vertical manner, the first contact points 121 and the second contact points 122 are spaced from each other by a horizontal offset. In addition to keeping a certain vertical distance between the first contact points and some of the second contact points, a certain horizontal distance is also maintained at the same time. For instance, as shown in FIG. 1, each of the non-vertical specific through-board connections 123 is provided with at least two bent portions, so that the first contact points 121 and the second contact points 122 is disposed at the certain horizontal distance. Besides, the bent portions are not limited to vertical, and the bent portions do not have any angular limit.

Moreover, according to another embodiment, a material of conductive wires of the specific through-board connections 123 is copper (Cu), gold (Au) or any material with conductive properties, so that the specific through via holes make the first contact points 121 be electrically connected to part of the second contact points 122. Apart from the method of disposing the conductive wires, the specific through-board connections 123 make the first contact points be electrically connected to part of the second contact points through a buried via hole (BVH), a blind via hole (BVH), a plated through hole (PTH), an electrical connector or any combination thereof.

The functional module 110 is further described as follows. The functional modules 110 are independently disposed on the semiconductor testing printed circuit board 120. For instance, the functional modules 110 are electrically connected to part of the first contact points 121 of the semiconductor testing printed circuit board 120 through a first conductive connecting device 111. The functional modules 110 respectively have time domain signals and clock rates provided and operated independently. In other words, even if each functional module 110 uses the same clock rate, the time domain signals connected to each functional controller is able to still operate independently and without interference, such as synchronously and the same phase, synchronously but different phase, or asynchronously. Therefore, each of the functional controllers can still be electrically connected to the same functional module 110. As well, each of the functional controllers receives the time domain signal from the functional module 110 in the synchronous or asynchronous manner, so as to test the performance of each of the functional controllers to the functional module 110 in parallel in the functional tests.

In the wafer probing testing, the functional controllers are disposed on the wafer 200 in various ways. According to an embodiment, the wafer 200 has the plurality of devices under test (DUTs), each of the DUTs has one or more functional controllers respectively.

According to another embodiment, the semiconductor testing apparatus 100a further comprises a primary space transformer device 130a. The primary space transformer device 130a is disposed on the second surface of the semiconductor testing printed circuit board 120 (for example, in FIG. 1, the lower side of the semiconductor testing printed circuit board 120, that is, a surface adjacent to the surface of the semiconductor testing printed circuit board 120 having the second contact points 122) to be electrically connected to the second contact points 122. The primary space transformer device 130 is a multilayer organic substrate (MLO), a multilayer ceramic substrate (MLC), a connector or any combination thereof.

Besides, the primary space transformer device 130a comprises a plurality of third contact points 131 and a plurality of fourth contact points 132.

The third contact points 131 are disposed on a third surface of the primary space transformer device 130a (for example, in FIG. 1, an upper side of the primary space transformer device 130a) to electrically connected to the second contact points 122 disposed on the semiconductor testing printed circuit board 120 through a second conductive connecting device 150, respectively. The second conductive connecting device 150 is a plurality of ball grid array (BGA) solder balls. A material of the first connecting device 150 is tin (Sn) or any material with conductive function, such as solder interconnection, solder balls, elastomer, POGO pins or any combination thereof, but the present disclosure is not limited thereto.

The fourth contact points 132 are disposed on a fourth surface of the primary space transformer device 130a opposite to the third surface (for example, in FIG. 1, a lower side of the primary space transformer device 130a) to electrically connected to the third contact points 131, respectively. A connection manner of the third contact points 131 and the fourth contact points 132 is same as the preceding connection manner of the first contact points 121 and the second contact points 122. According to another embodiment, the third contact points 131 are also electrically connected to the fourth contact points 132 in a vertical or non-vertical manner, respectively (for example, the conductive wires in FIG. 1). Additionally, when the third contact points 131 are electrically connected to the fourth contact points 132 in the non-vertical manner (for example, the conductive wires in FIG. 1), the conductive wires 133 is able to be provided with at least two bent portions, so that the third contact points 131 and the fourth contact points 132 may be arranged at a certain horizontal offset. The bent portions are not limited to being vertical, and the bent portions do not have any angular limitation.

According to another embodiment, as shown in FIG. 1, the semiconductor testing apparatus 100a also comprises probe pins 140. The probe pins 140 are disposed on the fourth surface of the primary space transformer device 130a (for example, in FIG. 1, the lower side of the primary space transformer device 130a, that is, the side of the primary space transformer device 130a with the fourth contact points 132) to be electrically connected to the specific fourth contact points 132, the wafer 200 and the functional controllers on the wafer 200. Besides, the specific fourth contact points 132 may be simply some of the fourth contact points 132, but not all the fourth contact points 132.

According to another embodiment, when the probe pins 140 are a vertical probe, the vertical probe is cobra probes, MEMS probes, wire probes, POGO pins or any combination thereof, but the present disclosure is not limited thereto. Further, according to another embodiment, in FIG. 1, the probe pins 140 comprise a plurality of probes 141 a plurality of guide plates 142 and 143. The probes 141 are fixed through the guide plates 142 and 143 to be electrically connected to the fourth contact points 132, the wafer 200 and the functional controllers on the wafer 200, respectively. Thus, the wafer 200 and the functional controllers on the wafer 200 receive signals from the functional module 110 independently to complete the functional tests of the functional controllers to the functional modules 110 synchronously or asynchronously.

Moreover, according to another embodiment, in FIG. 1, the semiconductor testing apparatus 100a also comprises a plurality of wafer bumps 210. The wafer bumps 210 are disposed on the wafer 200 and the functional controllers to be electrically connected to the probe pins 140, the wafer 200 and the functional controllers on the wafer 200. The wafer bumps 210 are gold bumps (comprising general golds and copper-nickel-gold bumps), solder bumps (comprising electroplating solder bumps and ball-mount solder bumps), cooper pillar bumps (CPB, comprising lead-free cooper pillar bumps) or any combination thereof.

### Final Testing—Embodiment 1

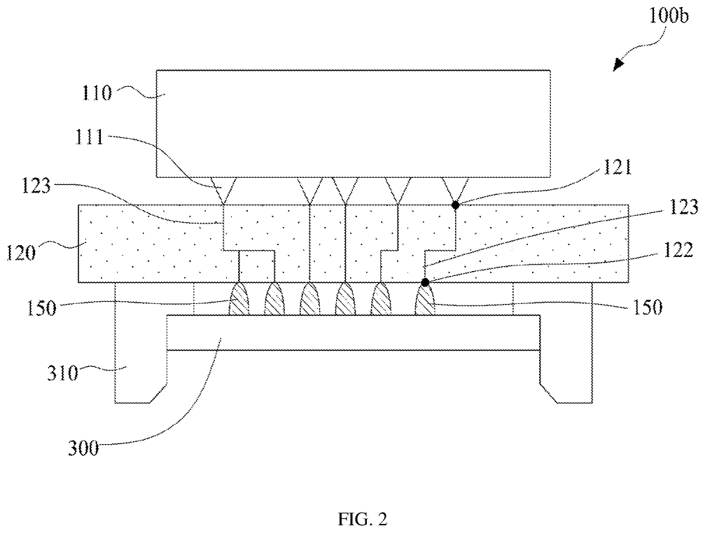

In addition to the semiconductor testing apparatus 100a configured to be used in wafer probing testing, a semiconductor testing apparatus 100b is configured to be used in a final testing. Referring to FIG. 2, FIG. 2 a schematic diagram of a semiconductor testing apparatus with a functional module, which is configured to test a functional controller with an independent time domain in a final testing. In FIG. 2, the present disclosure further provides the semiconductor testing apparatus 110b with a functional module. The semiconductor testing apparatus 110b is electrically connected to packaged integrated circuit devices (packaged IC devices) 300 to be tested for the final testing. Each of the DUTs 300 has a corresponding functional controller. Each of the functional controllers has an independent time domain, that is, the plurality of functional controllers correspond to one functional module 110, or one functional controller corresponds to one functional module 110. Hence, the semiconductor testing apparatus 110b subsequently performs the testing of functions of the functional controllers for the functional module synchronously or asynchronously.

Compared with the semiconductor testing apparatus 110a for the wafer probing testing shown in FIG. 1, the semiconductor testing apparatus 110b for the final testing also comprises a semiconductor testing printed circuit board 120 and a functional module 110. However, the main different is that the wafer is replaced with the packaged IC device 300 to be tested in the semiconductor testing apparatus 110b shown in FIG. 2. Thus, the semiconductor testing apparatus 110b is further configured to test finished semiconductor products (i.e., the packaged IC device 300) in the final testing. Other components relationships or connection manners of the semiconductor testing apparatus 100b are applicable to the components relationships or connection manners of the semiconductor testing apparatus 100a, which will not be repeated here.

In the final testing, the functional controllers in the packaged IC device 300 are configured in various ways. According to an embodiment, the packaged IC device 300 also has a plurality of devices under test (DUTs). Each of the DUTs may have one or more functional controllers respectively.

Furthermore, it is worth to mention that, in FIG. 2, the semiconductor testing apparatus 100b further comprises a plurality of sockets 310. The sockets 310 are disposed on a second surface of the semiconductor testing printed circuit board 120 (for example, in FIG. 2, a lower side of the semiconductor testing printed circuit board 120) to accommodate the packaged IC device 300 respectively. Further, according to another embodiment, the semiconductor testing apparatus 110b is respectively electrically connected to the specific second contact points 122, the packaged IC device 300 and the functional controller in the packaged IC device 300 through the second conductive connecting device 150. The specific second contact points 122 may simply be part of the second contact points 122, not all of the second contact points 122. That is, the plurality of functional controllers may correspond to one functional module 110, or one functional controller may correspond to one functional module 110.

Additionally, the second conductive connecting device 150 of the semiconductor testing apparatus 100b may be similar to, for example, the probe pins 140, the second conductive connecting device 150 or any combination thereof of the semiconductor testing apparatus 100a to be electrically connected to specific second contact points 122, the packaged IC device 300 and the functional controllers in the packaged IC device 300. Please refer to above for details, and the details will not be repeated here.

### Final Testing—Embodiment 2

Furthermore, the present disclosure also provides a semiconductor testing apparatus with a connected unit. The connected functional module is electrically connected to each socket and DUT by specific through-board connections penetrating a semiconductor testing printed circuit board. Since the specific through-board connections penetrating the semiconductor testing printed circuit board, the sockets/DUTs and the connected functional modules are electrically connected to each other with the shortest distance. Thus, a transmission distance of a signal in the transmission process is reduced, so as to improve the electrical performance of the DUTs with the connected functional module and reduce the signal attenuation caused by the transmission distance.

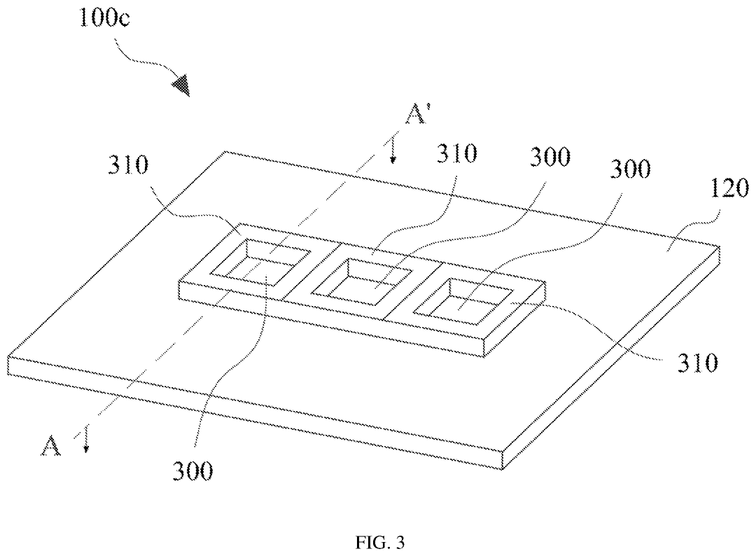

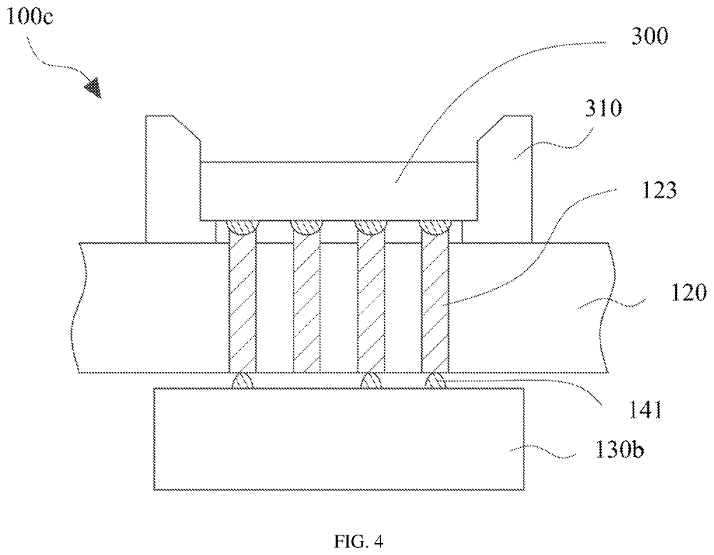

To clearly describe embodiments of the present disclosure, please refer to FIG. 3 and FIG. 4 at the same time. FIG. 3 is a schematic three-dimension diagram of a semiconductor testing device with a connected functional module according to an embodiment of the present disclosure. FIG. 4 is a cross-section diagram along a tangent A-A′ in FIG. 3 of a structure of the semiconductor testing device with the connected functional module according to an embodiment of the present disclosure. In FIG. 3, a semiconductor testing apparatus 100c with a second connected unit 130b comprises a semiconductor testing printed circuit board 120 and a plurality of second connected units 130b.

The semiconductor testing printed circuit board 120 comprises at least two sockets 310 and a plurality of specific through-board connections 123.

The at least two sockets are adjacently disposed on a second surface of the semiconductor testing printed circuit board 120 to make full use of the limited area of the semiconductor testing printed circuit board 120 and improve the usage per unit area of the semiconductor testing printed circuit board 120. The at least two sockets that have been disposed may be configured to separately and independently load at least one packaged IC device 300.

According to an embodiment of the present disclosure, the semiconductor testing printed circuit board 120 may simply comprise a socket configured to load the packaged IC device 300.

According to another embodiment of the present disclosure, the socket 310 and the specific through-board connections 123 are electrically connected with an electrical connection structure, such as pogo pins, elastomer, ball grid arrays (BGA), pins packaged by quad flat package (QFP) or quad flat no lead (QFN) or other electrical connection structure.

The specific through-board connections are disposed on a side of the socket not loading the device under test and penetrate through the semiconductor testing printed circuit board 120 to be electrically connected to the device under test. Moreover, the specific through-board connections 123 are electrically connected through a vias-in-pad (VIP) method, a copper-plating after plated-through holes (PTH) method, a copper-plating after laser-drilling, elastomer or other electrical connection method. The specific through-board connections 123 are electrically connected through the VIP or BGA adjacent to the specific through-board connections 123.

Besides, the different second connected units 130b have probes or terminals in different positions and combinations. Hence, the second connected functional modules 130b may be selectively electrically connected to part of the specific through via holes 123 to test the different electrical functions of the packaged IC device 300.

The second connected unit 130b is disposed on the second surface of the semiconductor testing printed circuit board 120 relative to the socket. The second connected unit 130b is electrically connected to the specific through-board connections 123 with the shortest distance, so as to reduce the attenuation of a transmission signal between the second connected unit 130b and the socket 310 during the transmission process. The shortest distance can ensure that the transmission process is carried out in an environment of low resistance, low capacitance and low inductance, so as to provide the electrical performance with high current and high-speed signals.

The preceding embodiments are the description in the final testing. Next, embodiments for the wafer probing testing and the final testing are further described, so that those skilled in the art can better understand the advantages and technical features of the present disclosure.

According to an embodiment, the probes 141 are POGO pins, elastomer or vertical conduction probes. Besides, a protruding length of the probe pins 141 is adjustable telescopically to closely contact the specific through-board connections 123. Alternatively, the probe pins 141 are adjacent to the specific through-board connections 123 to be electrically connected to the packaged IC device 300. The POGO pins comprise single pins (such as upright, tailed, double headed or floating) and connectors (such as upright or side-connected).

According to another embodiment of the present disclosure, the packaged IC device 300 is a solid-state drive controller (SSD controller). That is, according to an embodiment of the present disclosure, the semiconductor testing 100c apparatus with the connected unit is configured to test an integrated circuit that is an SSD controller or a memory controller.

According to another embodiment of the present disclosure, the second unit 130b may comprise a high-speed component, a low-noise component or a combination thereof.

Specifically, such high-speed components may comprise a solid-state relay (SSR), a high-speed connector, a memory, a radio-frequency (RF) passive device, a radio-frequency (RF) active device or a coaxial cable, such as RF cable assemblies, microwave cable assemblies, or a combination thereof.

Additionally, such high-speed signals of the high-speed component may comprise those of SERializer/DESerializer (SERDES), serial advanced technology attachment (SATA), peripheral component Interconnect express (PCIe), universal serial bus (USB), mobile industry processor interface (MIPI), high definition multimedia interface (HDMI), memory and radio frequency (RF). The memory interface may be a double data rate (DDR) synchronous dynamic random access memory interface, a flash memory interface or a combination thereof.

Moreover, such low-noise components may comprise an operational amplifier (OP), a digital to analog converter (DAC), an analog to digital converter (ADC), an image sensor, or a combination thereof.

According to another embodiment of the present disclosure, a high-density package of the device under test may be any available package, such as the ball grid array (BGA) package or a chip scale package (CSP).

In addition, the functional modules 110 can be stacked through the plurality of the connected units 130b of the semiconductor testing apparatus 100c, such as a stacked package on package (PoP). Thus, allowing that the test efficiency per unit area of a single integrated circuit test apparatus with the additional connected unit to be greatly improved. At the same time, the unit volume test efficiency of the plurality of integrated circuit test apparatus with the additional connected unit can also be greatly improved.

### A Semiconductor Testing Method

In addition, referring to FIG. 4, FIG. 4 is a cross-section diagram of a structure of the semiconductor testing device with the connected unit according to an embodiment of the present disclosure. The present disclosure further provides a semiconductor testing method, and the method comprises the following steps.

Firstly, the at least two sockets 310 are disposed adjacently on the second surface of the semiconductor testing printed circuit board 120. The semiconductor testing printed circuit board 120 has the plurality of specific through-board connections 123. The plurality of specific through-board connections 123 are disposed relative to the socket 310 and penetrate through the semiconductor testing printed circuit board 120.

Next, the plurality of second connected units 130b are disposed on the first surface of the semiconductor testing printed circuit board 120 opposite to the second surface relative to the sockets 310. The second connected units 130b are electrically connected to part of the specific through-board connections 123 to be electrically connected to the corresponding socket 310 and the specific second connected unit 130b with the shortest distance.

Further, the packaged IC devices 300 are disposed on the corresponding sockets. Thus, the packaged IC devices 300 can be tested in the final testing.

### Technical Effects

As stated as above, the present disclosure can achieve the technical effects as follows. Firstly, due to the specific through-board connections 123 disposed in the semiconductor testing printed circuit board 120, the contact points on the upper side and lower side of the semiconductor testing printed circuit board 123 may be electrically connected in a vertical or non-vertical manner (i.e., the first contact points 121 and the second contact points 122). Therefore, by stacking the functional modules 110 (electrically connected to the first contact points 121), the number of single test of the functional controllers on the wafer 200 or the packaged IC device 300 can be increased. At the same time, due to the arrangement of the first contact points and the second contact points, the plurality of independent functional controllers can be simultaneously contacted the second contact points respectively. By being electrically connected each of the functional controllers to the functional module, each of the functional controllers can be performed the functions of each of the functional controllers to the functional module in a synchronous or asynchronous manner with an independent and parallel time domain One the one hand, the present disclosure can reduce the time cost. On the other hand, the qualified functional controllers can be selected more quickly and efficiently without being limited by the spatial and/or time constraints of the related art.

Secondly, the present disclosure provides the semiconductor testing apparatus 100c with the connected unit, which can fully utilize the space of the upper side and the lower side of the semiconductor testing printed circuit board 120. That is, one or more packaged IC device 300 are disposed on the second surface of the semiconductor testing printed circuit board 120, and the plurality of the connected units with different electrical testing functions or uses are disposed on the first surface of the semiconductor testing printed circuit board with the shortest distance. Hence, it is no longer necessary to electrically connect the packaged IC device 300 and the connected unit by means of a conventional interconnection wiring which increases the distance therebetween. Consequently, the present disclosure can effectively utilize the semiconductor testing printed circuit board, so that the number of the packaged IC device 300 or DUTs that be accommodate per unit area is increased, and the utilization rate per unit area thereof is increased.

Thirdly, due to the arrangement of the sockets, the conductive via and the probe pins, the distance between the packaged IC devices 300 adjacent to the semiconductor testing apparatus 100c is ensured to be a constant and the same shortest distance. Therefore, the present disclosure can provide a better electrical performance while reducing signal attenuation during signal transmission.

Fourthly, different from the related art that requires several multi-site correlations, the distances of the signal transmission paths between the functional module and the functional controller of the present invention are the same. Moreover, even the placement of functional modules and circuit layout will not cause asymmetric characteristics problems. In this way, the testing accuracy will be greatly improved.

Accordingly, the embodiments of the present disclosure can not only solve the problems in the related art, but also greatly reduce the testing time and cost in semiconductor testing. Further, the embodiments of the present disclosure also help the competitiveness of semiconductor testing enhanced.

It should be understood that the examples and the embodiments described herein are for illustrative purpose only, and various modifications or changes in view of them will be suggested to those skilled in the art, and will be included in the spirit and scope of the application and the appendix with the scope of the claims.

What is claimed is:

1. A semiconductor testing apparatus, which is configured to test a functionality of an integrated circuit on a wafer or packaged IC devices, the semiconductor testing apparatus comprising:
a semiconductor testing printed circuit board, comprising:
a plurality of first contact points, disposed on a first surface of the semiconductor testing printed circuit board;
a plurality of second contact points, disposed on a second surface opposite to the first surface of the semiconductor testing printed circuit board; and
a plurality of specific through-board connections, disposed in the semiconductor testing printed circuit board to be electrically connected to the first contact points and part of the second contact points respectively, wherein each of the second contact points is electrically connected to one of the first contact points;
a functional module, disposed on the semiconductor testing printed circuit board, and electrically connected to the first contact points of the semiconductor testing printed circuit board;
a primary space transformer device of the semiconductor testing apparatus, disposed on the second surface of the semiconductor testing printed circuit board, and the primary space transformer device comprising:
a plurality of third contact points, disposed on a third surface of the primary space transformer device, and electrically connected to the second contact points respectively; a plurality of fourth contact points, disposed on a fourth surface opposite to the third surface of the primary space transformer device, wherein each of the fourth contact points is electrically connected to one of the third contact points; and
a plurality of probe pins, electrically connected to the fourth contact points and a functional controller on the wafer to independently test a functionality of the functional controller with the functional module in a synchronous or asynchronous time domain.

2. The semiconductor testing apparatus of claim 1, wherein the functional module is a dynamic random access memory, a static random access memory, a static dynamic random access memory, a flash memory or a combination thereof.

3. The semiconductor testing apparatus of claim 1, wherein the functional controller is a memory controller or a direct memory access controller.

4. The semiconductor testing apparatus of claim 1, wherein the second contact points are electrically connected to the packaged IC devices to independently test a functionality of the packaged IC devices with the functional module in a synchronous or asynchronous time domain.

5. The semiconductor testing apparatus of claim 3, further comprising:
a plurality of sockets, disposed on the semiconductor testing printed circuit board to accommodate the packaged IC devices.

6. The semiconductor testing apparatus of claim 1, wherein the probe pins are vertical probes components.

7. The semiconductor testing apparatus of claim 6, wherein the vertical probes components are cobra probes, MEMS probes, MEMS POGOs, wire probes, POGO pins, or a combination thereof.

8. The semiconductor testing apparatus of claim 4, wherein the first contact points electrically connected to the part of the second contact points are disposed apart from each other by a certain horizontal offset.

9. A semiconductor testing apparatus, comprising:
a semiconductor testing printed circuit board, comprising:
a plurality of first contact points, disposed on a first surface of the semiconductor testing printed circuit board;
a plurality of second contact points, disposed on a second surface opposite to the first surface of the semiconductor testing printed circuit board; and
a plurality of specific through-board connections, disposed in the semiconductor testing printed circuit board to be electrically connected to the first contact points and part of the second contact points; and
a functional module, disposed on the semiconductor testing printed circuit board, and electrically connected to the first contact points; and
a socket, disposed on the second surface of the semiconductor testing printed circuit board to accommodate a packaged IC device;
wherein the semiconductor testing apparatus respectively connects through specific contact points, the packaged IC device and an electronic device in the packaged IC device and the functional module;
wherein a functionality of the electronic device in the functional module is tested;
wherein the functionality of the electronic device in the functional module is tested by the semiconductor testing apparatus in a synchronous or asynchronous time domain.

10. The semiconductor testing apparatus of claim 9, wherein the electronic device is a memory controller, an encoding device, a baseband circuit, a processing unit, or an embedded controller.

11. A semiconductor testing apparatus with a connected unit:
a semiconductor testing printed circuit board, comprising:
at least two sockets, adjacently disposed on a second surface of the semiconductor testing printed circuit board to load a packaged IC device respectively; and
a plurality of specific through-board connections, disposed relative to the sockets and penetrating through the semiconductor testing printed circuit board to be electrically connected to the packaged IC device; and
a second connected unit, disposed on a first surface of the semiconductor testing printed circuit board relative to the sockets, and electrically connected to part of the specific through-board connections to electrically connect the second connected unit and the sockets with the shortest distance, so as to reduce a signal attenuation between the second connected unit and the sockets.

12. The semiconductor testing apparatus with the connected unit of claim 11, wherein the second connected unit has a plurality of probe pins to make electrical contact with the specific through-board connections directly.

13. The semiconductor testing apparatus with the connected unit of claim 12, wherein the probe pins are POGO pins, Elastomer or vertical conductive pins.

14. The semiconductor testing apparatus with the connected unit of claim 12, wherein the second connected unit comprises a high-speed component, a low-noise component or a combination thereof.

15. The semiconductor testing apparatus with the connected unit of claim 14, wherein the high-speed component comprises a solid-state relay (SSR), a high-speed connector, a memory, a radio-frequency (RF) passive device, a radio-frequency (RF) active device or a coaxial cable, such as RF cable assemblies or microwave cable assemblies.

16. The semiconductor testing apparatus with the connected unit of claim 15, wherein a high-speed signal of the high-speed component comprises a serial advanced technology attachment (SATA) interface, a peripheral component Interconnect express (PCIe) interface, a universal serial bus (USB) interface, a mobile industry processor interface (MIPI), a high definition multimedia interface (HDMI), a memory interface, a radio frequency (RF) interface, or a combination thereof.

17. The semiconductor testing apparatus with the connected unit of claim 16, wherein the memory interface is a double data rate (DDR) synchronous dynamic random access memory interface, a flash memory interface or a combination thereof.

18. The semiconductor testing apparatus with the connected unit of claim 14, wherein the low-noise component comprises an operational amplifier (OP), a digital to analog converter (DAC), an analog to digital converter (ADC), an image sensor or a combination thereof.

19. The semiconductor testing apparatus with the connected unit of claim 11, wherein a high-density package of the device under test may be any available package, such as the ball grid array (BGA) package or a chip scale package (CSP).

20. A semiconductor testing method with a connected unit, comprising the following steps:
disposing two sockets adjacently on a second surface of a semiconductor testing printed circuit board, wherein the semiconductor testing printed circuit board has a plurality of specific through-board connections, and the specific through-board connections disposed relative to the sockets and penetrate the semiconductor testing printed circuit board;
disposing a plurality of second connected units relative to the sockets on a first surface opposite to the second surface of the semiconductor testing printed circuit board, wherein the second connected units are electrically connected to part of the specific through-board connections; and
disposing a plurality of packaged IC devices on the sockets, wherein the packaged IC devices are electrically connected to part of the specific through-board connections to be electrically connected to the second connected units and the sockets with the shortest distance to perform a semiconductor testing.
